(19) United States
(12) Patent Application Publication
(10) Pub. No.: US 2016/0149547 A1
(43) Pub. Date: May 26, 2016

(54) AUTOMATED AUDIO ADJUSTMENT

(71) Applicant: Intel Corporation, Santa Clara, CA (US)

(72) Inventors: Tomer Rider, Naahryia (IL); Igor Tatourian, Santa Clara, CA (US)

(21) Appl. No.: 14/548,508

(22) Filed: Nov. 20, 2014

(51) Int. Cl. H03G 3/24

(52) U.S. Cl. CPC H03G 3/24

(57) ABSTRACT

Various systems and methods for automated audio adjustment are described herein. A processing system for automated audio adjustment may include a monitoring module to obtain contextual data of a listening environment; a user profile module to access a user profile of a listener; and an audio module to adjust an audio output characteristic based on the contextual data and the user profile, the audio output characteristic to be used in a media performance on a media playback device.

### TECHNICAL FIELD

Embodiments described herein generally relate to media playback and in particular, to a mechanism for automated audio adjustment.

### BACKGROUND

Audio is a frequent component to media, such as television, radio, film, etc. Different users and different situations impact the effectiveness of audio output. For example, a user may frequently adjust the volume of a song as the user passes from areas with low ambient noise to areas with higher ambient noise and vice versa. Some systems use noise cancellation, for example with destructive wave interference, in an attempt to cancel unwanted ambient noise.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 is a schematic drawing illustrating a listening environment, according to an embodiment;

FIG. 2 is a data and control flow diagram illustrating the various states of the system, according to an embodiment;

FIG. 3 is a flowchart illustrating a method for automated audio adjustment, according to an embodiment; and

FIG. 4 is a block diagram illustrating an example machine upon which any one or more of the techniques (e.g., methodologies) discussed herein may perform, according to an example embodiment.

### DETAILED DESCRIPTION

Systems and methods described herein provide a mechanism to automatically adjust the volume of a media presentation for a listener. The volume may be adjusted based on one or more of the following factors, including background noise levels; location, time, or context of the presentation; presence or absence of other people, possibly including age or gender as factors; and a model based on the listener's own volume adjustment habits. Using these factors, and perhaps others, the systems and methods discussed may learn a user's preferences and predict a user's preferred audio volume, audio effects (e.g., equalizer settings), etc. The systems and methods may work with various types of media presentation devices (e.g., stereo system, headphones, computer, smartphone, on-board vehicle infotainment system, television, etc.) and with various output forms (e.g., speakers, headphones, earbuds, etc.).

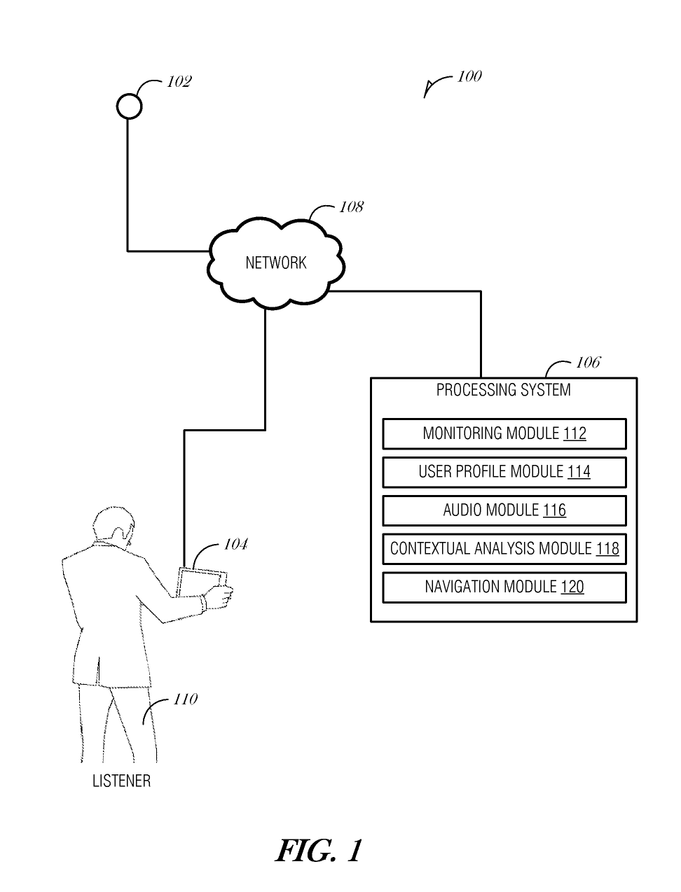

FIG. 1 is a schematic drawing illustrating a listening environment 100, according to an embodiment. The listening environment 100 includes a sensor 102 and a media playback device 104. While only one sensor 102 is illustrated in FIG. 1, it is understood that two or more sensors may be used. The sensor 102 may be integrated into the media playback device 104. The sensor 102 may be a camera, infrared sensor, microphone, accelerometer, thermometer, or the like. The sensor 102 may be a micro-electro-mechanical system (MEMS) or a macroscale component. The sensor 102 may detect temperature, pressure, inertial forces, magnetic fields, radiation, etc. The sensor 102 may be a standalone device (e.g., a ceiling-mounted camera) or an integrated device (e.g., a camera in a smartphone). The sensor 102 may be incorporated into a wearable device, such as a watch, glasses, or the like.

Further, the sensor 102 may also be configured to detect physiological indications. The sensor 102 may be any type of sensor, such as a contact-based sensor, optical sensor, temperature sensor, or the like. The sensor 102 may be adapted to detect a person's heart rate, skin temperature, brain wave activities, alertness (e.g., camera-based eye tracking), activity levels, or other physiological or biological data. The sensor 102 may be integrated into a wearable device, such as a wrist band, glasses, headband, chest strap, shirt, or the like. Alternatively, the sensor 102 may be integrated into a non-wearable system, such as a vehicle (e.g., seat sensor, inward facing cameras, infrared thermometers, etc.) or a bicycle. Several different sensors 102 may be installed or integrated into a wearable or non-wearable device to collect physiological or biological information.

The media playback device 104 may be any type of device with an audio output. The media playback device 104 may be a smartphone, laptop, tablet, music player, stereo system, in-vehicle infotainment system, or the like. The media playback device 104 may output audio to speakers or earphones.

A processing system 106 is connected to the media playback device 104 and the sensor 102 via a network 108. The processing system 106 may be incorporated into the media playback device 104, located local to the media playback device 104 as a separate device, or hosted in the cloud accessible via the network 108.

The network 108 includes any type of wired or wireless communication network or combinations of wired or wireless networks. Examples of communication networks include a local area network (LAN), a wide area network (WAN), the Internet, mobile telephone networks, plain old telephone (POTS) networks, and wireless data networks (e.g., Wi-Fi, 3G, and 4G LTE/LTE-A or WiMAX networks). The network 108 acts to backhaul the data to the core network (e.g., to the datacenter 106 or other destinations).

During operation, the processing system 106 monitors various aspects of the listening environment 100. These aspects include, but are not limited to, background noise levels, location, time, context of listening, presence of other people, identification or other characteristics of the listener or other people present, and the listener's audio adjustments. Based on these inputs and possibly others, the processing system 106 learns the listener's preferences over time. Using machine learning processes, the processing system 106 may then predict user preferences for various contexts. Various machine learning processes may be used including, but not limited to decision tree learning, association rule learning, artificial neural networks, inductive logic programming, Bayesian networks, and the like.

As an example, a listener 110 may watch television later at night. The listener's children may be asleep in the adjacent room. While the listener 110 is watching a television show, the volume of commercials, scenes, or other portions of the broadcast may vary. The processing system 106 may detect that the listener's children are asleep or trying to rest, and that the time is after a regular bedtime for the children. The processing system 106 may also detect the identity of the listener 110. Using this input, the processing system 106 may set the volume or other audio features in a certain way to avoid disturbing the listener's children. For example, the listener 110 may be identified as an older male who is known to have a slight hearing disability. Additional sensors in the listener's children's bedroom may provide insight on actual noise levels in the adjacent room. Based on these inputs, and possibly others, the processing system 106 may set the volume slightly higher to account for the listener's hearing loss and for the fact that the bedroom is fairly well sound insulated.

One mechanism to control the sound in this situation is to use a feedback loop. With a microphone sensor near the listener's position, the processing system 106 may determine the effective volume level. When a change in volume occurs due to a change in the broadcast programming (e.g., loud sound effects or a commercial with a different sound equalizer level), the volume of the media playback device 104 may be adjusted up or down to maintain approximately the target volume level.

Another mechanism to control the sound is to use pre-sampling. The processing system 106 may maintain or access a buffer of the media content in order to determine volume changes before they are played back through the media playback device 104 to the listener. In this manner, the processing system 106 may preemptively adjust the volume level or other audio feature before a volume spike or dip occurs.

While volume is one audio feature that may be automatically adjusted, it is understood that other features may also be adjusted. For example, equalizer levels may be changed to emphasize dialog (e.g., which are typically at higher frequencies) and de-emphasize sound effects (e.g., explosions are typically at lower frequencies). Additionally, in more sophisticated systems, individual sound tracks may be accessed and adjusted (e.g., control volume). In this way, the sound effects track may be output with a lower volume and the dialogue track may be output at a higher volume to accommodate a certain listener or context.

As another example, a MEMS device may be used to sense whether the listener is walking or running. Based on this evaluation, a volume setting or other audio setting may be adjusted. Such activity monitoring may be performed using an accelerometer (e.g., a MEMS accelerometer), blood pressure sensor, heart rate sensor, skin temperature sensor, or the like. For example, if a user is stationary (e.g., as determined by an accelerometer), supine (e.g., as determined by a posture sensor), and relatively low heart rate (e.g., as determined by a heart rate monitor), the volume may be lowered to reflect the possibility that the listener is attempting to fall asleep. The time of day, location of the listener, and other inputs may be used to confirm or invalidate this determination, and thus change the audio settings used.

In these situations described, the listener 110 is able to manually change the volume or other audio setting. When doing so, the processing system 106 captures such changes and uses the activities as input to the machine learning processes. As such, when the listener 110 interacts with the processing system 106, the processing system 106 becomes more efficient and accurate with respect to the listener's preferences.

FIG. 1 describes a processing system 106 for automated audio adjustment including a monitoring module 112 to obtain contextual data of a listening environment 100, the listening environment 100 including a listener 110. The processing system 106 may also include a user profile module 114 to access a user profile of the listener 110, and an audio module 116 to adjust an audio output characteristic based on the contextual data and the user profile, the audio output characteristic to be used in a media performance on a media playback device 104. The user profile may be stored on the media playback device or at the processing system 106. The processing system 106 may be incorporated into the media playback device 104 or may be separate. Several user profiles may be stored together and accessed, for example, when one of several users is using the media playback device 104.

In an embodiment, to obtain the contextual data, the monitoring module 112 is to access a health monitor, and the contextual data includes sensor data indicative of a physiological state of the listener 110. In a further embodiment, the health monitor is integrated into a wearable device worn by the listener 110. The health monitor may be a heart rate monitor, brain activity monitor, posture sensor, or the like.

In an embodiment, to obtain the contextual data, the monitoring module 112 is to analyze a video image. The contextual data may include data indicative of a number of people present in the listening environment 100, where the number of people is obtained by analyzing the video image. For example, a listening environment 100 may be equipped with one or more cameras (e.g., sensor 102), and using the video information, a count of people in or around the listening environment 100 may be obtained. Additional information may be obtained from video information, including people's identity, approximate age, gender, activity, or the like. Such information may be used to augment the contextual data and influence the audio output characteristics (e.g., raise or lower volume).

In an embodiment, the user profile comprises a history of media performances and of listening volumes. By tracking user activity and saving a history of what the user watched or listened to, when, for how long, and what listening volumes or other audio output characteristics were used, user preferences and general listening characteristics may be modeled. This history may be used in a machine learning process. Thus, in an embodiment, the user profile module 114 is to modify the user profile based on the contextual data. In a further embodiment, to modify the user profile, the user profile module 114 is to use a machine learning process. The user profile may be stored locally or remotely. For example, one copy of the user profile may be stored on a playback device 104 with another copy stored in the cloud, such as at the processing system 106 or at another server accessible via the network 108. With a network-accessible user profile, preferences, models, rules, and other data may be transmitted to any listening environment. For example, if the listener 110 travels and rents a car, or stays in a hotel, the user profile may be provided in these environments to modify audio output characteristics of devices playing back media in these environments (e.g., a car stereo or a television in a hotel room).

In an embodiment, the contextual data comprises information about other people present in the listening environment 100, and to modify the user profile, the user profile module 114 is to: capture a modification to audio output, the modification provided by the listener 119; and correlate the modification with the information about other people present in the listening environment 100. In a further embodiment, the information about other people present in the listening environment 100 is captured using sensors integrated into wearable devices worn by the other people present in the listening environment 100. For example, a listener 110 may wear a wearable sensor and his children may have their own wearable sensor capable of detecting physiological information. When the children are asleep in an adjacent room, e.g., their location and activity state may be detected by the wearable sensor, the volume of the media playback device 104 may be modified, such as by lowering the output volume. This action may be based on previous activities observed by the listener 110 where the listener 110 manually reduced the volume after determining that his children were asleep. Further, in this case, the listening environment 100 is understood to include any area where the media performance may be heard, which may include adjacent rooms or rooms above or below the room where the listener 110 is observing the media playback.

In an embodiment, the audio module 116 is to adjust, based on a physiological state of the other people present in the listening environment 100, as identified using the sensors integrated into the wearable devices worn by the other people present in the listening environment 100, the audio output characteristic.

In an embodiment, to modify the user profile based on the contextual data, the user profile module 114 is to: monitor behavior of the listener 110 over time with respect to the contextual data; build a model of listener preferences using the behavior; and use the model of listener preferences to adjust the audio output characteristic.

In an embodiment, the user profile comprises a schedule, and to adjust the audio output characteristic based on the contextual data and the user profile, the audio module 116 is to: identify a location associated with an appointment on the schedule; determine that the listener 110 is at the location; and adjust the audio output characteristic when the listener 110 is at the location. For example, a listener 110 may keep an electronic calendar and include a daily workout appointment in the calendar. When the listener 110 arrives at the gym to workout, the listener's media playback device 104 may automatically increase the output volume to accommodate louder than usual ambient noise. After the listener's schedule workout appointment is over, the media playback device 104 may reduce the volume to the previous setting.

In an embodiment, to obtain the contextual data of the listening environment 100, the monitoring module 112 is to determine an activity of the listener; and to adjust the audio output characteristic, the audio module 116 is to adjust an output volume based on the activity of the listener 110. In a further embodiment, the activity of the listener 110 includes an exercise activity, and to adjust the audio output characteristic, the audio module 116 is to increase the output volume of the media performance. In another embodiment, the activity of the listener 110 includes a rest activity, and to adjust the audio output characteristic, the audio module 116 is to decrease the output volume of the media performance. The rest activity may be detected using a heart rate monitor, posture sensor, or the like, and may determine that the listener 110 is prone or asleep. In response, the output volume may be lowered or muted.

In an embodiment, the audio output characteristic comprises an audio volume setting. In an embodiment, the audio output characteristic comprises an audio equalizer setting. In an embodiment, the audio output characteristic comprises an audio track selection. Other audio output characteristics may be used, or combinations of these audio output characteristics may be used together.

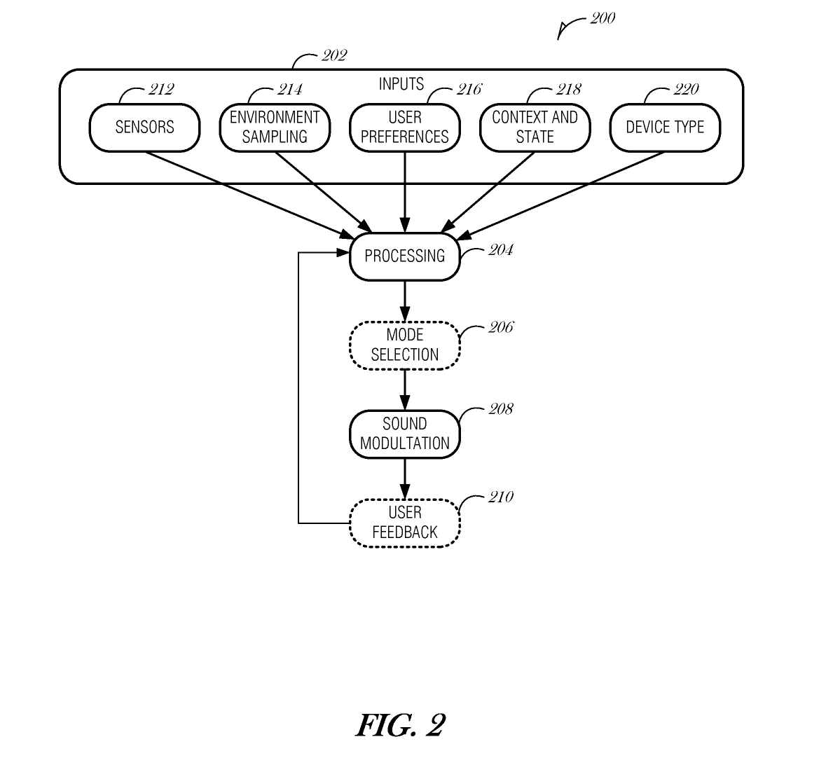

FIG. 2 is a data and control flow diagram illustrating the various states 200 of the system, according to an embodiment. FIG. 2 includes an input group 202 of one or more inputs. The inputs from the input group 202 are fed to a processing block 204. The processing block 204 integrates inputs and creates possible sound scenes for a listener. An optional mode selection block 206 may be provided to a listener to select one of the sound scenes created by the processing block 204. Alternatively, the sound scene is selected by the system and used by the sound modulation block 208 to change the characteristics of the audio output. An optional user feedback block 210 may be available to capture, record, and provide input back to the processing block 204 in a feedback loop.

The input group 202 may include various inputs, including sensor input 212, environment sampling input 214, user preferences 216, context and state 218, and device type 220. The sensor input 212 includes various sensor data, such as ambient noise, temperature, biological/physiological data, etc. The environment sampling input 214 may include various data related to the operating environment, such as an accelerometer (e.g., a MEMS device) used to determine activity level or listener posture. User preferences 216 may include user characteristics provided by the user (e.g., listener 110), such as age, hearing condition, gender, and the like. User preferences 216 may also include data indicating a user's preferred volume or audio adjustments for particular locations, events, times, or the like. For example, a user preference may be related to location, such that when a user is listening to media in their home workout room, the preferred volume may be set at a higher volume than when the user is listening to media in their home office.

The context and state 218 input provides the place, time, and situations the device and user are found. The context and state 218 inputs may be derived from sensor input 212 or environment sampling input 214.

The device type input 220 indicates the media playback device, such as a smartphone, in-vehicle infotainment system music player, notebook, tablet, music player, etc. The device type input 220 may also include information about additional devices, such as headphones, earbuds, speakers, etc.

Using some or all of the inputs from the input group 202, the processing block 204 analyzes the available input and creates one or more possible sound scenes. A sound scene describes various aspects of a listening environment, such as a location, context, environmental condition, media type, etc. The sound scene may be labeled with descriptive names, such as “MOVIE,” “CAR,” or “TALK RADIO” and may be associated with an audio output profile. The audio output profile may define the volume, equalizer settings, track selections, and the like, to adaptively mix the output audio of a media playback.

In some embodiments, the listener is provided a mode selection function (mode selection block 206), where the user may select a sound scene. The selection function may be provided on a graphical user interface and may present the descriptive names associated with each available sound scene.

The sound modulation block 208 operates to alter the output audio according to the selected sound scene. The sound scene may be automatically selected by the system or manually selected by a user (at mode selection block 206). Sound modulation may include operations such as reducing or increasing the volume, adding or removing intensity of certain frequency ranges (e.g., adjusting equalizer settings), or enabling/disabling or modifying tracks in an audio output. The audio is output during the sound modulation block 208.

In some embodiments, the listener may provide feedback (block 210). The user feedback may be in any form, including manually adjusting volume, using voice commands to increase/decrease volume, using gesture commands, or the like. The user feedback may be fed back into the processing block 204, which may use the feedback for further decision making. Additionally or optionally, the user feedback may be stored or incorporated as a user preference (block 216).

As another illustrative example of operation, a user may occasionally drive a scenic roadway on Sundays. The system may detect the user's identity, that the user is in a vehicle and travelling a particular route, and determine that the user is using an in-vehicle infotainment system to listen to a satellite radio station. The system may also determine that because the convertible top is down, the user is exposed to increased ambient road and wind noise. Based on these inputs, the system may increase the volume of the in-vehicle infotainment system. The volume setting may be obtained from a sound scene that is associated with the context of the media playback. When the user puts on noise canceling headphones to reduce some of the ambient wind noise, the system may detect this additional device usage and reduce the volume of the audio presentation. Later, when the user rotates the volume control on the stereo head to increase the volume, the system may capture such actions and store the modified volume as a target volume for the next time the particular sound scene occurs.

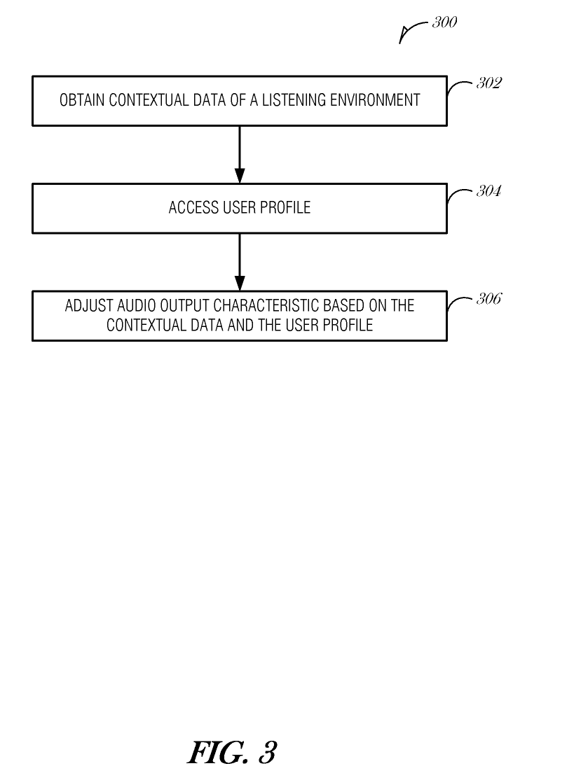

FIG. 3 is a flowchart illustrating a method 300 for automated audio adjustment, according to an embodiment. At block 302, contextual data of a listening environment is obtained at a processing system. In an embodiment, obtaining contextual data comprises accessing a health monitor, and wherein the contextual data comprises sensor data indicative of a physiological state of the listener. In a further embodiment, the health monitor is integrated into a wearable device worn by the listener.

In an embodiment, obtaining contextual data comprises analyzing a video image, and wherein the contextual data comprises data indicative of a number of people present in the listening environment, the number of people obtained by analyzing the video image.

In an embodiment, the user profile comprises a history of media performances and of listening volumes.

At block 304, a user profile of a listener is accessed. The listening environment includes the listener.

At block 306, an audio output characteristic is adjusted based on the contextual data and the user profile, the audio output characteristic to be used in a media performance on a media playback device.

In a further embodiment, the method 300 includes modifying the user profile based on the contextual data. In a further embodiment, modifying the user profile is performed using a machine learning process. In another embodiment, the contextual data comprises information about other people present in the listening environment, and modifying the user profile comprises: capturing a modification to audio output, the modification provided by the listener; and correlating the modification with the information about other people present in the listening environment. In a further embodiment, the information about other people present in the listening environment is captured using sensors integrated into wearable devices worn by the other people present in the listening environment. In a further embodiment, the method 300 includes adjusting, based on a physiological state of the other people present in the listening environment, as identified using the sensors integrated into the wearable devices worn by the other people present in the listening environment, the audio output characteristic.

In an embodiment, modifying the user profile based on the contextual data comprises: monitoring behavior of the listener over time with respect to the contextual data; building a model of listener preferences using the behavior; and using the model of listener preferences to adjust the audio output characteristic.

In an embodiment, the user profile comprises a schedule, and adjusting the audio output characteristic based on the contextual data and the user profile comprises: identifying a location associated with an appointment on the schedule; determining that the listener is at the location; and adjusting the audio output characteristic when the listener is at the location.

In an embodiment, obtaining the contextual data of the listening environment comprises determining an activity of the listener; and adjusting the audio output characteristic comprises adjusting an output volume based on the activity of the listener.

In an embodiment, the activity of the listener includes an exercise activity, and adjusting the audio output characteristic comprises increasing the output volume of the media performance. In another embodiment, the activity of the listener includes a rest activity, and adjusting the audio output characteristic comprises decreasing the output volume of the media performance.

In embodiments, the audio output characteristic comprises an audio volume setting, an audio equalizer setting, or an audio track selection. Other audio output characteristics may be used, or combinations of audio characteristics may be used.

Embodiments may be implemented in one or a combination of hardware, firmware, and software. Embodiments may also be implemented as instructions stored on a machine-readable storage device, which may be read and executed by at least one processor to perform the operations described herein. A machine-readable storage device may include any non-transitory mechanism for storing information in a form readable by a machine (e.g., a computer). For example, a machine-readable storage device may include read-only memory (ROM), random-access memory (RAM), magnetic disk storage media, optical storage media, flash-memory devices, and other storage devices and media.

Examples, as described herein, may include, or may operate on, logic or a number of components, modules, or mechanisms. Modules may be hardware, software, or firmware communicatively coupled to one or more processors in order to carry out the operations described herein. Modules may be hardware modules, and as such modules may be considered tangible entities capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations. Accordingly, the term hardware module is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software; the general-purpose hardware processor may be configured as respective different modules at different times. Software may accordingly configure a hardware processor, for example, to constitute a particular module at one instance of time and to constitute a different module at a different instance of time. Modules may also be software or firmware modules, which operate to perform the methodologies described herein.

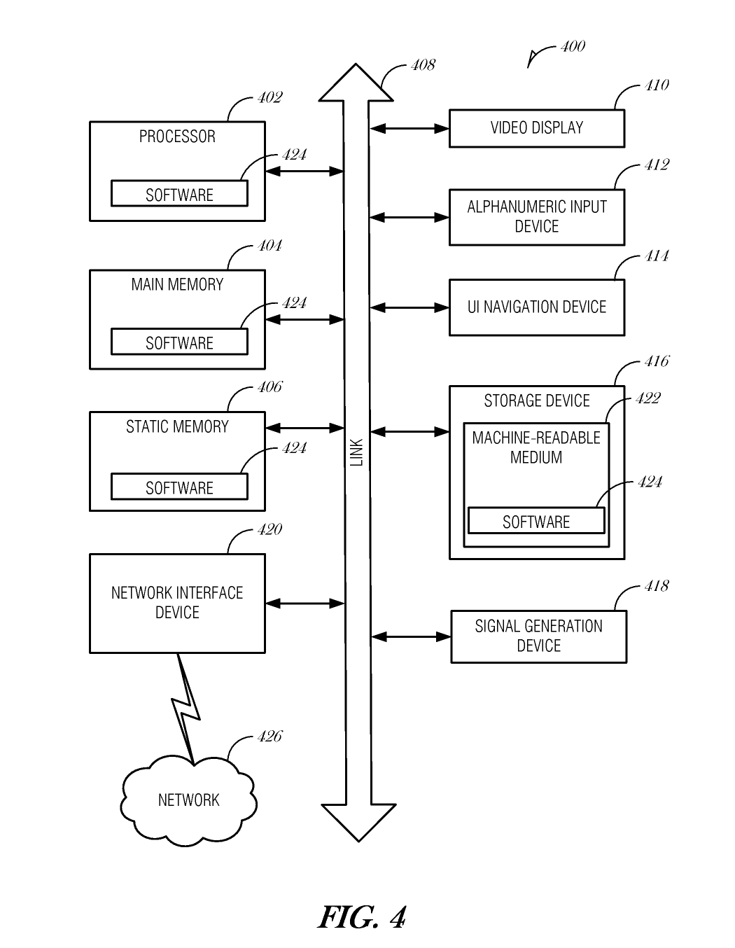

FIG. 4 is a block diagram illustrating a machine in the example form of a computer system 400, within which a set or sequence of instructions may be executed to cause the machine to perform any one of the methodologies discussed herein, according to an example embodiment. In alternative embodiments, the machine operates as a standalone device or may be connected (e.g., networked) to other machines. In a networked deployment, the machine may operate in the capacity of either a server or a client machine in server-client network environments, or it may act as a peer machine in peer-to-peer (or distributed) network environments. The machine may be an onboard vehicle system, set-top box, wearable device, personal computer (PC), a tablet PC, a hybrid tablet, a personal digital assistant (PDA), a mobile telephone, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein. Similarly, the term “processor-based system” shall be taken to include any set of one or more machines that are controlled by or operated by a processor (e.g., a computer) to individually or jointly execute instructions to perform any one or more of the methodologies discussed herein.

Example computer system 400 includes at least one processor 402 (e.g., a central processing unit (CPU), a graphics processing unit (GPU) or both, processor cores, compute nodes, etc.), a main memory 404 and a static memory 406, which communicate with each other via a link 408 (e.g., bus). The computer system 400 may further include a video display unit 410, an alphanumeric input device 412 (e.g., a keyboard), and a user interface (UI) navigation device 414 (e.g., a mouse). In one embodiment, the video display unit 410, input device 412 and UI navigation device 414 are incorporated into a touch screen display. The computer system 400 may additionally include a storage device 416 (e.g., a drive unit), a signal generation device 418 (e.g., a speaker), a network interface device 420, and one or more sensors (not shown), such as a global positioning system (GPS) sensor, compass, accelerometer, or other sensor.

The storage device 416 includes a machine-readable medium 422 on which is stored one or more sets of data structures and instructions 424 (e.g., software) embodying or utilized by any one or more of the methodologies or functions described herein. The instructions 424 may also reside, completely or at least partially, within the main memory 404, static memory 406, and/or within the processor 402 during execution thereof by the computer system 400, with the main memory 404, static memory 406, and the processor 402 also constituting machine-readable media.

While the machine-readable medium 422 is illustrated in an example embodiment to be a single medium, the term “machine-readable medium” may include a single medium or multiple media (e.g., a centralized or distributed database, and/or associated caches and servers) that store the one or more instructions 424. The term “machine-readable medium” shall also be taken to include any tangible medium that is capable of storing, encoding or carrying instructions for execution by the machine and that cause the machine to perform any one or more of the methodologies of the present disclosure or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks.

The instructions 424 may further be transmitted or received over a communications network 426 using a transmission medium via the network interface device 420 utilizing any one of a number of well-known transfer protocols (e.g., HTTP). Examples of communication networks include a local area network (LAN), a wide area network (WAN), the Internet, mobile telephone networks, plain old telephone (POTS) networks, and wireless data networks (e.g., Wi-Fi, 3G, and 4G LTE/LTE-A or WiMAX networks). The term “transmission medium” shall be taken to include any intangible medium that is capable of storing, encoding, or carrying instructions for execution by the machine, and includes digital or analog communications signals or other intangible medium to facilitate communication of such software.

### ADDITIONAL NOTES & EXAMPLES

Example 1 includes subject matter for automated audio adjustment (such as a device, apparatus, or machine) comprising: a monitoring module to obtain contextual data of a listening environment; a user profile module to access a user profile of a listener; and an audio module to adjust an audio output characteristic based on the contextual data and the user profile, the audio output characteristic to be used in a media performance on a media playback device.

In Example 2, the subject matter of Example 1 may include, wherein to obtain the contextual data, the monitoring module is to access a health monitor, and wherein the contextual data comprises sensor data indicative of a physiological state of the listener.

In Example 3, the subject matter of any one of Examples 1 to 2 may include, wherein the health monitor is integrated into a wearable device worn by the listener.

In Example 4, the subject matter of any one of Examples 1 to 3 may include, wherein to obtain the contextual data, the monitoring module is to analyze a video image, and wherein the contextual data comprises data indicative of a number of people present in the listening environment, the number of people obtained by analyzing the video image.

In Example 5, the subject matter of any one of Examples 1 to 4 may include, wherein the user profile comprises a history of media performances and of listening volumes.

In Example 6, the subject matter of any one of Examples 1 to 5 may include, wherein the user profile module is to modify the user profile based on the contextual data.

In Example 7, the subject matter of any one of Examples 1 to 6 may include, wherein to modify the user profile, the user profile module is to use a machine learning process.

In Example 8, the subject matter of any one of Examples 1 to 7 may include, wherein the contextual data comprises information about other people present in the listening environment, and wherein to modify the user profile, the user profile module is to: capture a modification to audio output, the modification provided by the listener; and correlate the modification with the information about other people present in the listening environment.

In Example 9, the subject matter of any one of Examples 1 to 8 may include, wherein the information about other people present in the listening environment is captured using sensors integrated into wearable devices worn by the other people present in the listening environment.

In Example 10, the subject matter of any one of Examples 1 to 9 may include, wherein the audio module is to adjust, based on a physiological state of the other people present in the listening environment, as identified using the sensors integrated into the wearable devices worn by the other people present in the listening environment, the audio output characteristic.

In Example 11, the subject matter of any one of Examples 1 to 10 may include, wherein to modify the user profile based on the contextual data, the user profile module is to: monitor behavior of the listener over time with respect to the contextual data; build a model of listener preferences using the behavior; and use the model of listener preferences to adjust the audio output characteristic.

In Example 12, the subject matter of any one of Examples 1 to 11 may include, wherein the user profile comprises a schedule, and wherein to adjust the audio output characteristic based on the contextual data and the user profile, the audio module is to: identify a location associated with an appointment on the schedule; determine that the listener is at the location; and adjust the audio output characteristic when the listener is at the location.

In Example 13, the subject matter of any one of Examples 1 to 12 may include, wherein to obtain the contextual data of the listening environment, the monitoring module is to determine an activity of the listener; and wherein to adjust the audio output characteristic, the audio module is to adjust an output volume based on the activity of the listener.

In Example 14, the subject matter of any one of Examples 1 to 13 may include, wherein the activity of the listener includes an exercise activity, and wherein to adjust the audio output characteristic, the audio module is to increase the output volume of the media performance.

In Example 15, the subject matter of any one of Examples 1 to 14 may include, wherein the activity of the listener includes a rest activity, and wherein to adjust the audio output characteristic, the audio module is to decrease the output volume of the media performance.

In Example 16, the subject matter of any one of Examples 1 to 15 may include, wherein the audio output characteristic comprises an audio volume setting.

In Example 17, the subject matter of any one of Examples 1 to 16 may include, wherein the audio output characteristic comprises an audio equalizer setting.

In Example 18, the subject matter of any one of Examples 1 to 17 may include, wherein the audio output characteristic comprises an audio track selection.

Example 19 includes subject matter for automated audio adjustment (such as a method, means for performing acts, machine readable medium including instructions that when performed by a machine cause the machine to performs acts, or an apparatus to perform) comprising: obtaining at a processing system, contextual data of a listening environment; accessing a user profile of a listener; and adjusting an audio output characteristic based on the contextual data and the user profile, the audio output characteristic to be used in a media performance on a media playback device.

In Example 20, the subject matter of Example 19 may include, wherein obtaining contextual data comprises accessing a health monitor, and wherein the contextual data comprises sensor data indicative of a physiological state of the listener.

In Example 21, the subject matter of any one of Examples 19 to 20 may include, wherein the health monitor is integrated into a wearable device worn by the listener.

In Example 22, the subject matter of any one of Examples 19 to 21 may include, wherein obtaining contextual data comprises analyzing a video image, and wherein the contextual data comprises data indicative of a number of people present in the listening environment, the number of people obtained by analyzing the video image.

In Example 23, the subject matter of any one of Examples 19 to 22 may include, wherein the user profile comprises a history of media performances and of listening volumes.

In Example 24, the subject matter of any one of Examples 19 to 23 may include, further comprising modifying the user profile based on the contextual data.

In Example 25, the subject matter of any one of Examples 19 to 24 may include, wherein modifying the user profile is performed using a machine learning process.

In Example 26, the subject matter of any one of Examples 19 to 25 may include, wherein the contextual data comprises information about other people present in the listening environment, and wherein modifying the user profile comprises: capturing a modification to audio output, the modification provided by the listener; and correlating the modification with the information about other people present in the listening environment.

In Example 27, the subject matter of any one of Examples 19 to 26 may include, wherein the information about other people present in the listening environment is captured using sensors integrated into wearable devices worn by the other people present in the listening environment.

In Example 28, the subject matter of any one of Examples 19 to 27 may include, further comprising adjusting, based on a physiological state of the other people present in the listening environment, as identified using the sensors integrated into the wearable devices worn by the other people present in the listening environment, the audio output characteristic.

In Example 29, the subject matter of any one of Examples 19 to 28 may include, wherein modifying the user profile based on the contextual data comprises: monitoring behavior of the listener over time with respect to the contextual data; building a model of listener preferences using the behavior; and using the model of listener preferences to adjust the audio output characteristic.

In Example 30, the subject matter of any one of Examples 19 to 29 may include, wherein the user profile comprises a schedule, and wherein adjusting the audio output characteristic based on the contextual data and the user profile comprises: identifying a location associated with an appointment on the schedule; determining that the listener is at the location; and adjusting the audio output characteristic when the listener is at the location.

In Example 31, the subject matter of any one of Examples 19 to 30 may include, wherein obtaining the contextual data of the listening environment comprises determining an activity of the listener; and wherein adjusting the audio output characteristic comprises adjusting an output volume based on the activity of the listener.

In Example 32, the subject matter of any one of Examples 19 to 31 may include, wherein the activity of the listener includes an exercise activity, and wherein adjusting the audio output characteristic comprises increasing the output volume of the media performance.

In Example 33, the subject matter of any one of Examples 19 to 32 may include, wherein the activity of the listener includes a rest activity, and wherein adjusting the audio output characteristic comprises decreasing the output volume of the media performance.

In Example 34, the subject matter of any one of Examples 19 to 33 may include, wherein the audio output characteristic comprises an audio volume setting.

In Example 35, the subject matter of any one of Examples 19 to 34 may include, wherein the audio output characteristic comprises an audio equalizer setting.

In Example 36, the subject matter of any one of Examples 19 to 35 may include, wherein the audio output characteristic comprises an audio track selection.

Example 37 includes at least one computer-readable medium for automated audio adjustment comprising instructions, which when executed by a machine, cause the machine to: obtain at a processing system, contextual data of a listening environment; access a user profile of a listener; and adjust an audio output characteristic based on the contextual data and the user profile, the audio output characteristic to be used in a media performance on a media playback device.

Example 38 includes at least one machine-readable medium including instructions, which when executed by a machine, cause the machine to perform operations of any of the Examples 19-36.

Example 39 includes an apparatus comprising means for performing any of the Examples 19-36.

Example 40 includes subject matter for automated audio adjustment (such as a device, apparatus, or machine) comprising: means for obtaining at a processing system, contextual data of a listening environment; means for accessing a user profile of a listener; and means for adjusting an audio output characteristic based on the contextual data and the user profile, the audio output characteristic to be used in a media performance on a media playback device.

In Example 41, the subject matter of Example 40 may include, wherein the means for obtaining contextual data comprises means for accessing a health monitor, and wherein the contextual data comprises sensor data indicative of a physiological state of the listener.

In Example 42, the subject matter of any one of Examples 40 to 41 may include, wherein the health monitor is integrated into a wearable device worn by the listener.

In Example 43, the subject matter of any one of Examples 40 to 42 may include, wherein the means for obtaining contextual data comprises means for analyzing a video image, and wherein the contextual data comprises data indicative of a number of people present in the listening environment, the number of people obtained by analyzing the video image.

In Example 44, the subject matter of any one of Examples 40 to 43 may include, wherein the user profile comprises a history of media performances and of listening volumes.

In Example 45, the subject matter of any one of Examples 40 to 44 may include, further comprising means for modifying the user profile based on the contextual data.

In Example 46, the subject matter of any one of Examples 40 to 45 may include, wherein modifying the user profile is performed using a machine learning process.

In Example 47, the subject matter of any one of Examples 40 to 46 may include, wherein the contextual data comprises information about other people present in the listening environment, and wherein the means for modifying the user profile comprises: means for capturing a modification to audio output, the modification provided by the listener; and means for correlating the modification with the information about other people present in the listening environment.

In Example 48, the subject matter of any one of Examples 40 to 47 may include, wherein the information about other people present in the listening environment is captured using sensors integrated into wearable devices worn by the other people present in the listening environment.

In Example 49, the subject matter of any one of Examples 40 to 48 may include, further comprising means for adjusting, based on a physiological state of the other people present in the listening environment, as identified using the sensors integrated into the wearable devices worn by the other people present in the listening environment, the audio output characteristic.

In Example 50, the subject matter of any one of Examples 40 to 49 may include, wherein the means for modifying the user profile based on the contextual data comprises: means for monitoring behavior of the listener over time with respect to the contextual data; means for building a model of listener preferences using the behavior; and means for using the model of listener preferences to adjust the audio output characteristic.

In Example 51, the subject matter of any one of Examples 40 to 50 may include, wherein the user profile comprises a schedule, and wherein the means for adjusting the audio output characteristic based on the contextual data and the user profile comprises: means for identifying a location associated with an appointment on the schedule; means for determining that the listener is at the location; and means for adjusting the audio output characteristic when the listener is at the location.

In Example 52, the subject matter of any one of Examples 40 to 51 may include, wherein the means for obtaining the contextual data of the listening environment comprises means for determining an activity of the listener; and wherein the means for adjusting the audio output characteristic comprises means for adjusting an output volume based on the activity of the listener.

In Example 53, the subject matter of any one of Examples 40 to 52 may include, wherein the activity of the listener includes an exercise activity, and wherein the means for adjusting the audio output characteristic comprises means for increasing the output volume of the media performance.

In Example 54, the subject matter of any one of Examples 40 to 53 may include, wherein the activity of the listener includes a rest activity, and wherein the means for adjusting the audio output characteristic comprises means for decreasing the output volume of the media performance.

In Example 55, the subject matter of any one of Examples 40 to 54 may include, wherein the audio output characteristic comprises an audio volume setting.

In Example 56, the subject matter of any one of Examples 40 to 55 may include, wherein the audio output characteristic comprises an audio equalizer setting.

In Example 57, the subject matter of any one of Examples 40 to 56 may include, wherein the audio output characteristic comprises an audio track selection.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

What is claimed is:

1. A processing system for automated audio adjustment, the processing system comprising:
a monitoring module to obtain contextual data of a listening environment;
a user profile module to access a user profile of a listener; and
an audio module to adjust an audio output characteristic based on the contextual data and the user profile, the audio output characteristic to be used in a media performance on a media playback device.

2. The system of claim 1, wherein to obtain the contextual data, the monitoring module is to access a health monitor, and wherein the contextual data comprises sensor data indicative of a physiological state of the listener.

3. The system of claim 2, wherein the health monitor is integrated into a wearable device worn by the listener.

4. The system of claim 1, wherein to obtain the contextual data, the monitoring module is to analyze a video image, and wherein the contextual data comprises data indicative of a number of people present in the listening environment, the number of people obtained by analyzing the video image.

5. The system of claim 1, wherein the user profile comprises a history of media performances and of listening volumes.

6. The system of claim 1, wherein the user profile module is to modify the user profile based on the contextual data.

7. The system of claim 6, wherein to modify the user profile, the user profile module is to use a machine learning process.

8. The system of claim 6, wherein the contextual data comprises information about other people present in the listening environment, and
wherein to modify the user profile, the user profile module is to:
capture a modification to audio output, the modification provided by the listener; and
correlate the modification with the information about other people present in the listening environment.

9. The system of claim 8, wherein the information about other people present in the listening environment is captured using sensors integrated into wearable devices worn by the other people present in the listening environment.

10. The system of claim 9, wherein the audio module is to adjust, based on a physiological state of the other people present in the listening environment, as identified using the sensors integrated into the wearable devices worn by the other people present in the listening environment, the audio output characteristic.

11. The system of claim 6, wherein to modify the user profile based on the contextual data, the user profile module is to:
monitor behavior of the listener over time with respect to the contextual data;
build a model of listener preferences using the behavior; and
use the model of listener preferences to adjust the audio output characteristic.

12. The system of claim 1, wherein the user profile comprises a schedule, and
wherein to adjust the audio output characteristic based on the contextual data and the user profile, the audio module is to:
identify a location associated with an appointment on the schedule;
determine that the listener is at the location; and
adjust the audio output characteristic when the listener is at the location.

13. The system of claim 1, wherein to obtain the contextual data of the listening environment, the monitoring module is to determine an activity of the listener; and wherein to adjust the audio output characteristic, the audio module is to adjust an output volume based on the activity of the listener.

14. The system of claim 13, wherein the activity of the listener includes an exercise activity, and wherein to adjust the audio output characteristic, the audio module is to increase the output volume of the media performance.

15. The system of claim 13, wherein the activity of the listener includes a rest activity, and wherein to adjust the audio output characteristic, the audio module is to decrease the output volume of the media performance.

16. The system of claim 1, wherein the audio output characteristic comprises an audio volume setting.

17. The system of claim 1, wherein the audio output characteristic comprises an audio equalizer setting.

18. The system of claim 1, wherein the audio output characteristic comprises an audio track selection.

19. A method for automated audio adjustment, the method comprising:
obtaining at a processing system, contextual data of a listening environment;
accessing a user profile of a listener; and
adjusting an audio output characteristic based on the contextual data and the user profile, the audio output characteristic to be used in a media performance on a media playback device.

20. The method of claim 19, wherein obtaining contextual data comprises accessing a health monitor, and wherein the contextual data comprises sensor data indicative of a physiological state of the listener.

21. The method of claim 20, wherein the health monitor is integrated into a wearable device worn by the listener.

22. At least one machine-readable medium including instructions for automated audio adjustment, which when executed by a machine, cause the machine to:
obtain at a processing system, contextual data of a listening environment;
access a user profile of a listener; and
adjust an audio output characteristic based on the contextual data and the user profile, the audio output characteristic to be used in a media performance on a media playback device.

23. The machine-readable medium of claim 22, further comprising instruction to modify the user profile based on the contextual data.

24. The machine-readable medium of claim 23, wherein modifying the user profile is performed using a machine learning process.

25. The machine-readable medium of claim 23, wherein the contextual data comprises information about other people present in the listening environment, and
wherein modifying the user profile comprises:
capturing a modification to audio output, the modification provided by the listener; and
correlating the modification with the information about other people present in the listening environment.
